(19) United States
(12) Patent Application Publication
(10) Pub. No.: US 2011/0227610 A1
(43) Pub. Date: Sep. 22, 2011

(54) SELECTOR CIRCUIT

(75) Inventor: Hidehito KITAMURA, Osaka (JP)

(73) Assignee: RICOH COMPANY, LTD., Tokyo (JP)

(21) Appl. No.: 13/042,677

(22) Filed: Mar. 8, 2011

(30) Foreign Application Priority Data
Mar. 17, 2010 (JP) 2010-060173

(51) Int. Cl. H03K 17/00

(52) U.S. Cl. 327/99

(57) ABSTRACT

A selector circuit for selecting and outputting plural pieces of output data from input data including plural bits, in which each of the pieces of the output data including plural bits is provided. The selector circuit includes plural first swap circuits, each of the bits of the input data being input to any of the plural first swap circuits, the plural first swap circuits being configured to reorder and output the input bits or output the input bits without reordering; a bus configured to transfer the bits output from the first swap circuits; and plural data field specifying circuits respectively configured to select and take out a predetermined number of continuous bits on the bus. Plural bits taken out by any of the data field specifying circuits are included in the respective pieces of the output data.

### BACKGROUND OF THE INVENTION

1. Field of the Invention

The present invention relates to a selector circuit for selecting desired data from data received in a data transfer system and transmitting the selected data to a subsequent circuit, and particularly relates to a selector circuit for selecting RGB data from received data in an image data transfer system.

2. Description of the Related Art

There has been a system using an LVDS (low voltage differential signaling) transmitter and an LVDS receiver as the image data transfer system as described in Patent Document 1. In the image data transfer system described in Patent Document 1, the LVDS transmitter converts parallel data into serial data and transmits the serial data, and the LVDS receiver converts the received serial data into the parallel data.

FIG. 7 is a block diagram illustrating an example of a conventional image data transfer system. Serial data transmitted from an LVDS transmitter circuit 101 is received by an LVDS receiver circuit 102 and converted into parallel data of, for example, 7 bits×5 channels (CH0 through CH4). The 35-bit data after the conversion include image data of each of RGB and control data (for example, LSYNC data indicating a timing to capture data). The data output from the LVDS receiver circuit 102 is transmitted to a selector circuit 103. From the data transmitted from the LVDS receiver circuit 102, the selector circuit 103 selects the R data and control data and transmits the selected data to a R data capture circuit 104a, selects the G data and control data and transmits the selected data to a G data capture circuit 104b, and selects the B data and control data and transmits the selected data to a B data capture circuit 104c.

If a bit order of data is the same in any image data transfer system, image data of each of RGB and control data output from the LVDS receiver circuit 102 can be transmitted to the subsequent R data capture circuit 104a, G data capture circuit 104b, and B data capture circuit 104c as they are. However, an order of data on the serial data to be transmitted may be somewhat different depending on the LVDS transmitter circuit 101. In accordance with the different order of data, a bit order of data output from the LVDS receiver circuit 102 is also different. Therefore, if a subsequent circuit of the LVDS receiver circuit 102 is changed every time a configuration of the image data transfer system changes, design steps are increased. In order to avoid this change of the subsequent circuit, a circuit for reordering the bit order is required (for example, see Patent Document 2). In the example illustrated in FIG. 7, the required number of 35:1 multiplexers (MUX) for selecting one bit from 35-bit input data are provided in the selector circuit 103.

In the selector circuit 103 illustrated in FIG. 7, the 35-bit data transmitted from the LVDS receiver circuit 102 is temporarily stored in a data register 111 and then transmitted via a 35-bit internal bus 112 to 31 multiplexers (MUX) 113a through 113g. Specifically, ten multiplexers 113a through 113b are provided for the R data. Each of the multiplexers 113a through 113b selects one of 10-bit R data, namely RDATA[0] through RDATA[9], and transmits the selected data to the R data capture circuit 104a. Further, ten multiplexers 113c through 113d are provided for the G data. Each of the multiplexers 113c through 113d selects one of 10-bit G data, namely GDATA[0] through GDATA[9], and transmits the selected data to the G data capture circuit 104b. Furthermore, ten multiplexers 113e through 113f are provided for the B data. Each of the multiplexers 113e through 113f selects one of 10-bit B data, namely BDATA[0] through BDATA[9], and transmits the selected data to the B data capture circuit 104c. In addition, one multiplexer 113g selects control data LSYNC and transmits the control data LSYNC to the R data capture circuit 104a, G data capture circuit 104b, and B data capture circuit 104c. In a setting register 106, the selections of bits by the multiplexers 113a through 113g are set. Setting information in the setting register 106 are controlled in a software manner by a controller 105 (for example, a processor of the image data transfer system). As a result, the subsequent circuit of the LVDS receiver circuit 102 is not required to be changed no matter how the bit order of data output from the LVDS receiver circuit 102 changes.

However, the selector circuit illustrated in FIG. 7 simply includes an equal number of multiplexers to the number of bits of the output data, and the setting information is required to be held in the setting register 106 for each of the bits. Therefore, there has been a problem in that a circuit scale is increased.
[Patent Document 1] Japanese Patent Application Publication No. 2002-169770
[Patent Document 2] Japanese Patent Application Publication No. H10-78935

### SUMMARY OF THE INVENTION

It is an object of at least one embodiment of the invention to solve the above-described problem and provide a selector circuit which can deal with the change of bit order of received data in a data transfer system flexibly to some extent while suppressing the increase of circuit scale.

According to one aspect of the invention, a selector circuit for selecting and outputting plural pieces of output data from input data including plural bits, in which each of the pieces of the output data including plural bits is provided. The selector circuit includes plural first swap circuits, each of the bits of the input data being input to any of the plural first swap circuits, the plural first swap circuits being configured to reorder and output the input bits or output the input bits without reordering; a bus configured to transfer the bits output from the first swap circuits; and plural data field specifying circuits respectively configured to select and take out a predetermined number of continuous bits on the bus. Plural bits taken out by any of the data field specifying circuits are included in the respective pieces of the output data.

### BRIEF DESCRIPTION OF THE DRAWINGS

FIG. 1 is a block diagram illustrating a schematic configuration of an image data transfer system according to a first embodiment of the invention;

FIG. 2 is a block diagram illustrating a detailed configuration of a channel swap circuit 11a illustrated in FIG. 1;

FIG. 3 is a block diagram illustrating a schematic configuration of an image data transfer system according to a second embodiment of the invention;

FIG. 4 is a block diagram illustrating a detailed configuration of a data swap circuit 16a illustrated in FIG. 3;

FIG. 5 is a schematic diagram for describing the image data transfer system illustrated in FIG. 3;

FIG. 6 is a schematic diagram for describing operations of the image data transfer system illustrated in FIG. 3; and

FIG. 7 is a block diagram illustrating a schematic configuration of a conventional image data transfer system.

### DETAILED DESCRIPTION OF THE PREFERRED EMBODIMENTS

### First Embodiment

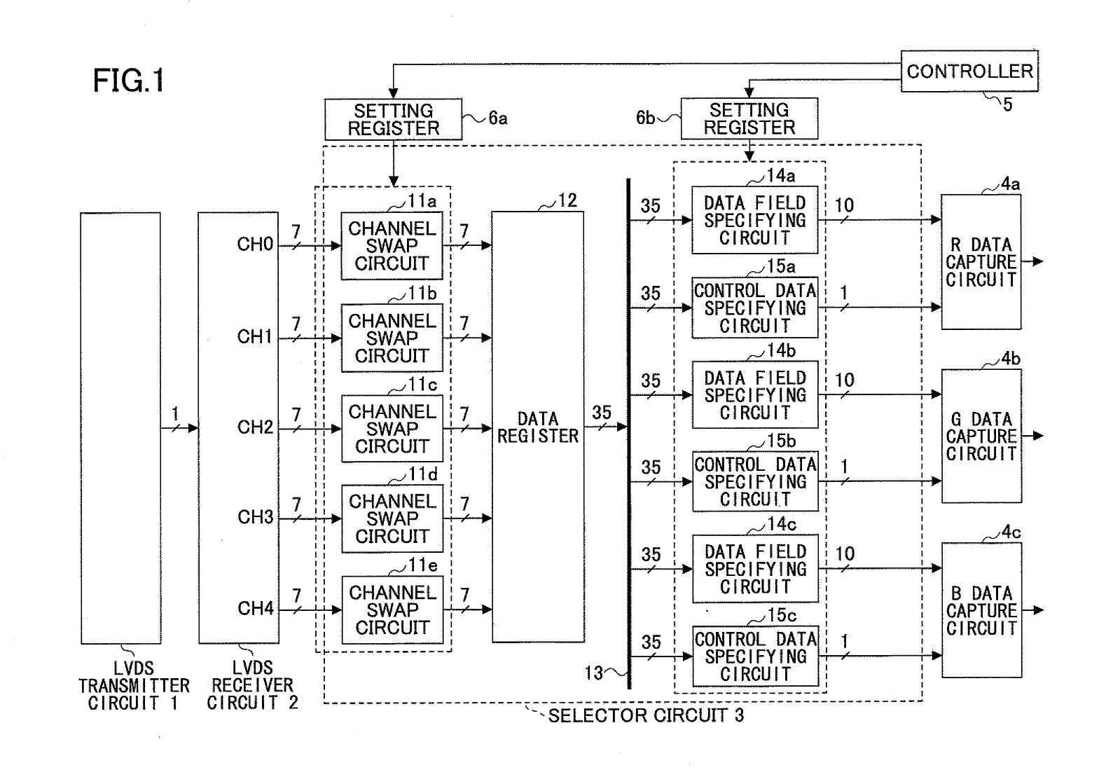

FIG. 1 is a block diagram illustrating a schematic configuration of an image data transfer system according to the first embodiment of the invention. In FIG. 1, serial data transmitted from an LVDS transmitter circuit 1 is received by an LVDS receiver circuit 2 and converted into parallel data of, for example, 7 bits×5 channels (CH0 through CH4). The 35-bit data after the conversion include image data of each of RGB and control data. In the example of FIG. 1, for example, the 35-bit data include 10-bit R data, 10-bit G data, 10-bit B data, and 1-bit control data (for example, LSYNC data indicating a timing to capture data). The 35-bit data output from the LVDS receiver circuit 2 are transmitted to a selector circuit 3. The selector circuit 3 selects, from the data transmitted from the LVDS receiver circuit 2, the R data and control data and transmits the selected data to a R data capture circuit 4a, selects the G data and control data and transmits the selected data to a G data capture circuit 4b, and selects the B data and control data and transmits the selected data to a B data capture circuit 4c.

The selector circuit 3 reorders a bit order of the data transmitted from the LVDS receiver circuit 2 in order to deal with a difference in the bit order of the data output by the LVDS receiver circuit 2 caused by a difference in a data order of the serial data transmitted from the LVDS transmitter circuit 1. As a precondition, the serial data transmitted from the LVDS transmitter circuit 1 is configured so that the respective bits of the R data, G data, and B data are arranged continuously after the conversion by the LVDS receiver circuit 2, or configured so that the respective bits of the R data, G data, and B data are arranged continuously by reordering the bit orders of respective channels after the conversion.

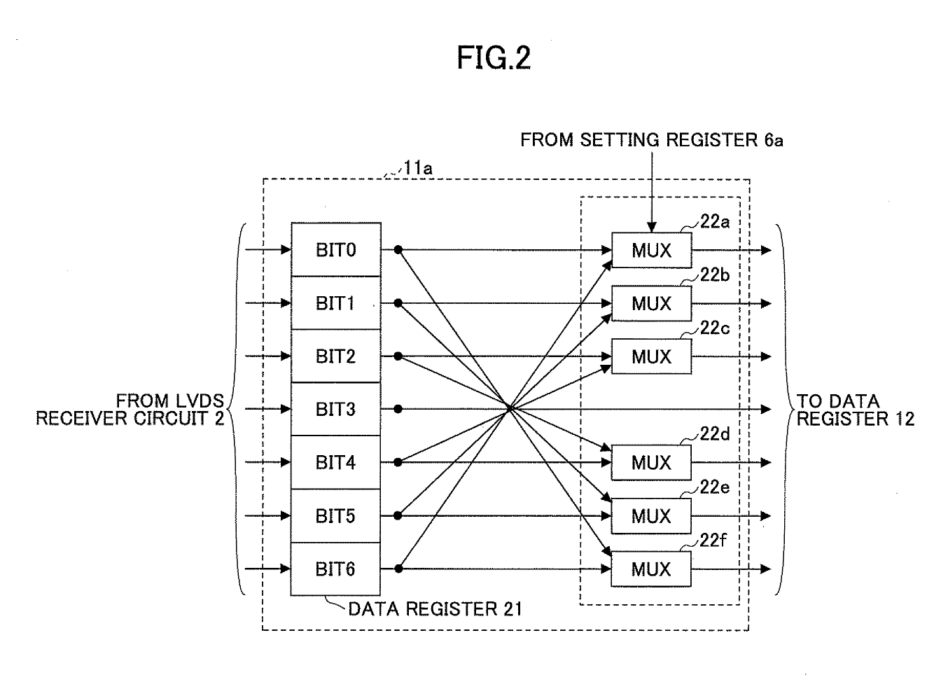

In the selector circuit 3, the channel swap circuits 11a through 11e reorder bit orders of respective channels of the data transmitted from the LVDS receiver circuit 2, or let the data transmitted from the LVDS receiver circuit 2 pass through as they are without reordering. As each of the channel swap circuits 11a through 11e, a circuit that sets a bit order in the channel in an ascending order or a descending order can preferably be used. FIG. 2 is a block diagram illustrating a detailed configuration of the channel swap circuit 11a. The data transmitted from the LVDS receiver circuit 2 is temporarily stored in a data register 21 and then transmitted to multiplexers (MUX) 22a through 22f as illustrated in FIG. 2. Each of the multiplexers 22a through 22f is a 2:1 multiplexer that selects and outputs one of two input bits. When bits 0 through 6 are input in an ascending order as illustrated in FIG. 2 and a bit order is not reordered, the bits 0 through 6 are output in the ascending order as they are. When the bit order of the input bits is reordered, the bits 0 through 6 are output in a descending order (namely, in a reversed bit order). Whether or not each of the multiplexers 22a through 22f reorders the bit order is set in a setting register 6a. Setting information in the setting register 6a is controlled in a software manner by a controller 5 (for example, a processor of the image data transfer system). The channel swap circuits 11b through 11e are also configured in a similar manner to the channel swap circuit 11a illustrated in FIG. 2. Data output from the channel swap circuits 11a through 11e are temporarily stored in a data register 12. In this manner, the selector circuit 3 of this embodiment selects whether or not the bit order is reordered depending on the data transmitted from the LVDS transmitter circuit 1, whereby the respective bits of the R data, G data, and B data can be in continuously arranged states in the data register 12 and subsequent circuits.

The data output from the channel swap circuits 11a through 11e are temporarily stored in the data register 12 and then transmitted via a 35-bit internal bus 13 to data field specifying circuits 14a, 14b, 14c, and control data specifying circuits 15a, 15b, and 15c. The data field specifying circuit 14a specifies only a bit at a start position of the R data from the continuously arranged 35-bit data including the R data, G data, and B data; takes out a 10-bit range starting from this specified bit as a data field of the R data; and transmits the data field of the R data to the R data capture circuit 4a. In a similar manner, the data field specifying circuit 14b specifies only a bit at a start position of the G data from the 35-bit data; takes out a 10-bit range starting from this specified bit as a data field of the G data; and transmits the data field of the G data to the G data capture circuit 4b. In the similar manner, the data field specifying circuit 14c specifies only a bit at a start position of the B data from the 35-bit data; takes out a 10-bit range starting from this specified bit as a data field of the B data; and transmits the data field of the B data to the B data capture circuit 4c. Each of the control data specifying circuits 15a, 15b, and 15c specifies one bit including the control data (for example, the LSYNC data) from the 35-bit data, takes out the control data of this specified bit, and transmits the control data to the R data capture circuit 4a, G data capture circuit 4b, or B data capture circuit 4c. The data taken out by the control data specifying circuits 15a, 15b, and 15c may be the same data (that is, the same bit is specified) or individually different data as well (that is, different bits are specified). The bits at the start positions specified by the data field specifying circuits 14a, 14b, and 14c; and the bits specified by the control data specifying circuits 15a, 15b, and 15c are set in a setting register 6b. Setting information in the setting register 6b are controlled in a software manner by the controller 5.

The selector circuit 3 configured as described above can transmit image data of each of RGB and control data in an appropriate bit order to the subsequent R data capture circuit 4a, G data capture circuit 4b, and B data capture circuit 4c.

A designer of the image data transfer system provided with the selector circuit 3 of this embodiment selects whether the bit order is to be reordered by the channel swap circuits 11a through 11e, and which bits are to be specified and taken out by the data field specifying circuits 14a, 14b, and 14c and the control data specifying circuits 15a, 15b, and 15c depending on the data transmitted from the LVDS transmitter circuit 1. The designer then determines the setting information in the setting registers 6a and 6b according to these selections. In this manner, using the selector circuit 3 of this embodiment allows dealing with the change of bit order of the data received in the data transfer system flexibly to some extent while suppressing the increase of circuit scale when designing an image data transfer system. In particular, for preventing the increase of circuit scale, it is advantageous to use a simple circuit (see FIG. 2) as the channel swap circuits 11a through 11e.

### Second Embodiment

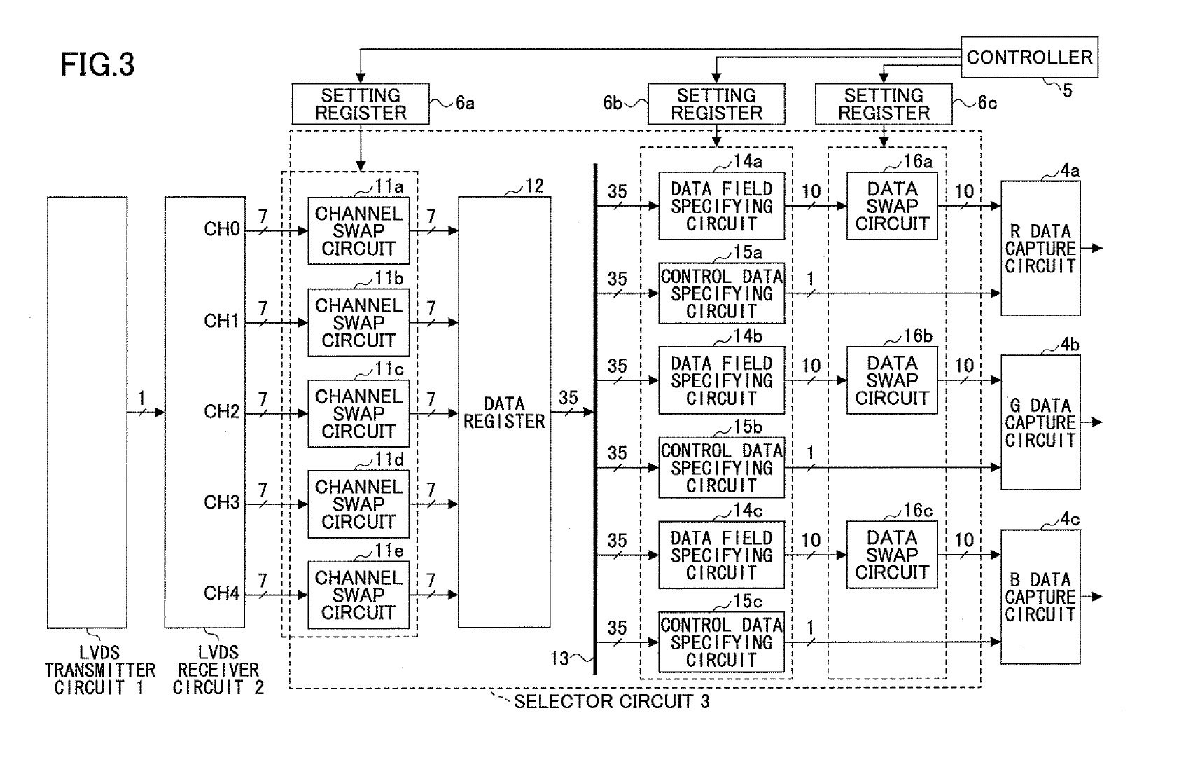

FIG. 3 is a block diagram illustrating a schematic configuration of an image data transfer system according to the second embodiment of the invention. In addition to the configuration of the selector circuit 3 of the first embodiment, the selector circuit 3 of this embodiment includes data swap circuits 16a, 16b, and 16c in a subsequent stage of the data field specifying circuits 14a, 14b, and 14c.

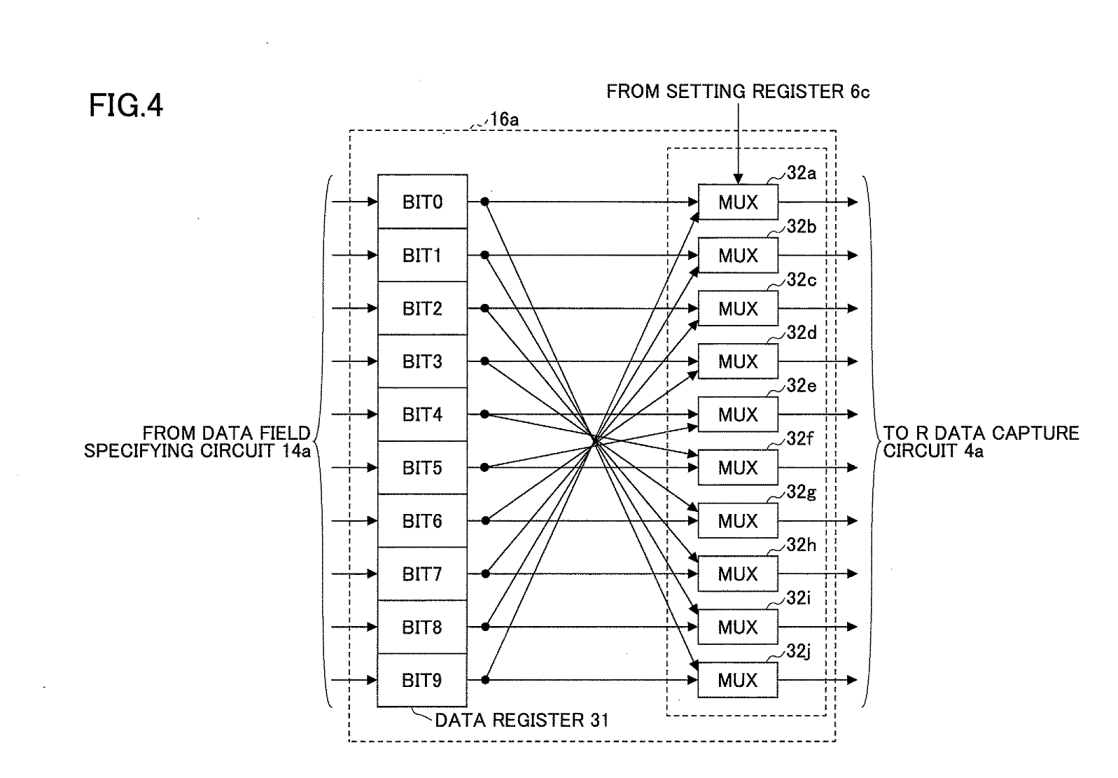

Each of the data swap circuits 16a, 16b, and 16c can select whether or not the respective bit orders of the R data, G data, and B data output from the data field specifying circuits 14a, 14b, and 14c are reordered as required. A circuit that sets an order of bits in the channel in the ascending order or descending order can be preferably used as the data swap circuits 16a, 16b, and 16c in a similar manner to the channel swap circuits 11a through 11e. FIG. 4 is a block diagram illustrating a detailed configuration of the data swap circuit 16a. Data transmitted from the data field specifying circuit 14a are temporarily stored in a data register 31 and then transmitted to multiplexers (MUX) 32a through 32j as illustrated in FIG. 4. Each of the multiplexers 32a through 32j is a 2:1 multiplexer which selects and outputs one of two input bits. Whether or not each of the multiplexers 32a through 32j reorders the bits is set in a setting register 6c. Setting information in the setting register 6c is controlled in a software manner by the controller 5. The data swap circuits 16b and 16c are also configured in a similar manner to the data swap circuit 16a illustrated in FIG. 4. Data output from the data swap circuits 16a, 16b, and 16c are transmitted to the R data capture circuit 4a, G data capture circuit 4b, and B data capture circuit 4c, respectively.

In this manner, the selector circuit 3 of this embodiments selects whether the bits of the R data, G data, and B data output from the data field specifying circuits 14a, 14b, and 14c are reordered as required, whereby the respective bits of the R data, G data, and B data can be output in bit orders desirable as image data for subsequent circuits.

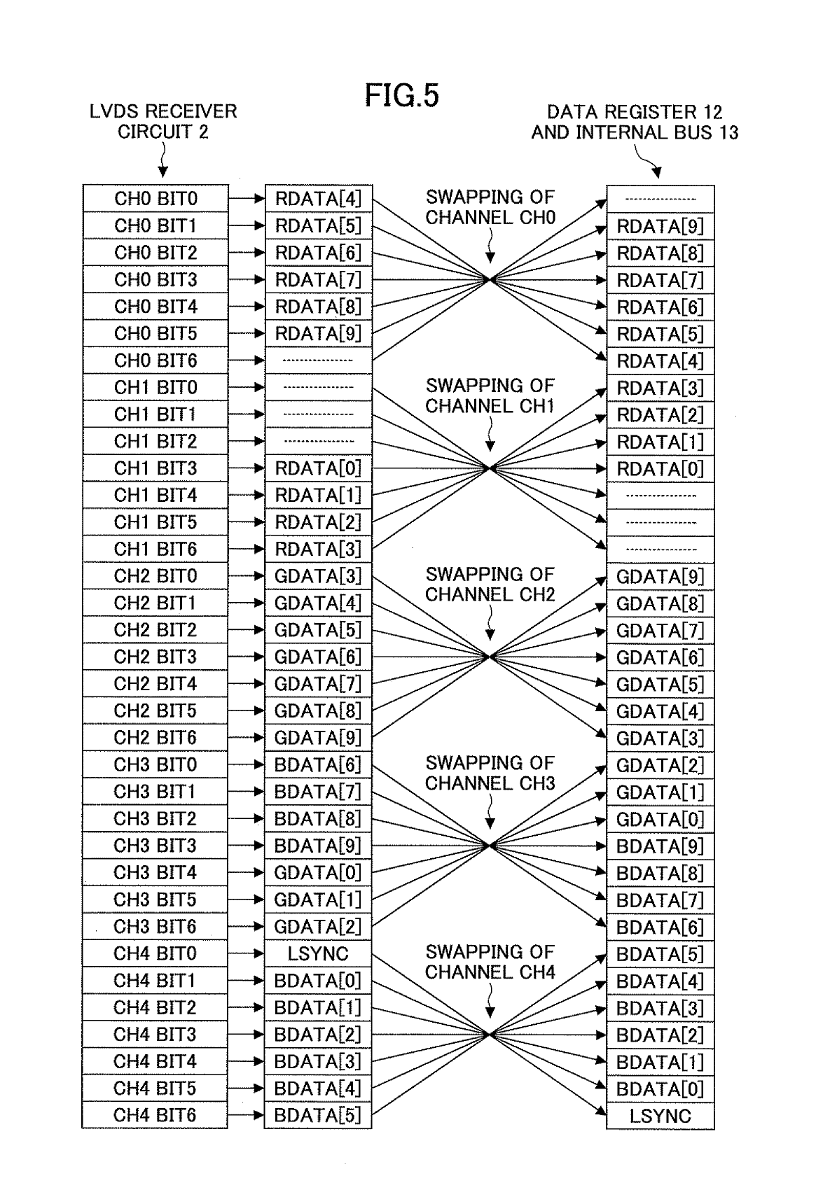

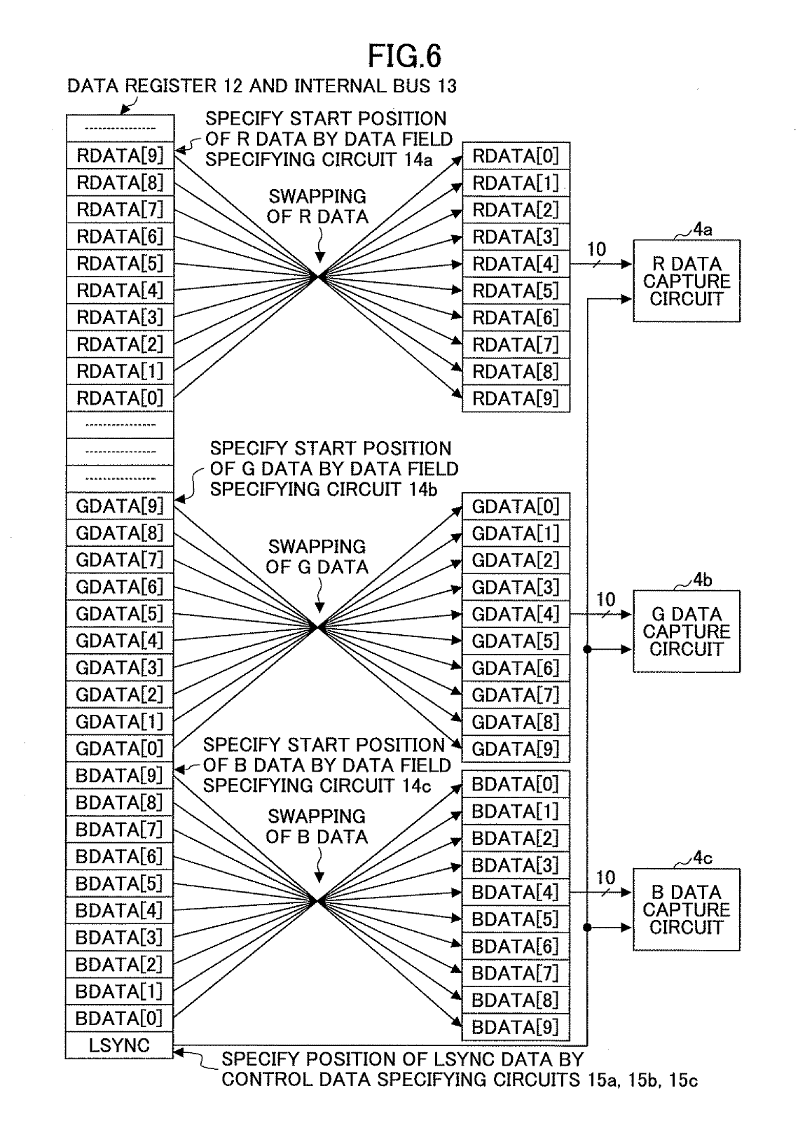

FIGS. 5 and 6 are schematic diagrams for describing operations of the image data transfer system illustrated in FIG. 3. FIGS. 5 and 6 specifically show how the selector circuit 3 of this embodiment selects bit orders of input data. The total of 35-bit data are input by 7 bits×5 channels from the LVDS receiver circuit 2 to the selector circuit 3. These input data include 10-bit R data (RDATA), 10-bit G data (GDATA), and 10-bit B data (BDATA) as image data, and 1-bit LSYNC data (LSYNC) as control data. In the illustrated case, respective bits of the R data, respective bits of the G data, and respective bits of the B data, which are not arranged continuously, are configured to be arranged continuously by reordering the orders of bits in each channel. Therefore, the bit order is reordered by using the channel swap circuits 11a through 11e. As a result, the R data, G data, and B data in which the bits are arranged continuously can be obtained at the data register 12 and internal bus 13. Subsequently, the R data, G data, and B data are taken out by the data field specifying circuits 14a, 14b, and 14c, respectively. Specifically, 10-bit regions are taken out from respective start positions of the R data, G data, and B data, which are specified by the data field specifying circuits 14a, 14b, and 14c, respectively. Bits of the R data, G data, and B data taken out by the data field specifying circuits 14a, 14b, and 14c, respectively, are reordered by using the data swap circuits 16a, 16b, and 16c, respectively. The R data, G data, and B data with the reordered bits are transmitted to the R data capture circuit 4a, G data capture circuit 4b, and B data capture circuit 4c, respectively. The respective control data specifying circuits 15a, 15b, and 15c specify and take out one bit including the control data LSYNC from the 35-bit data, and transmit the bit that has been taken out to the R data capture circuit 4a, G data capture circuit 4b, and B data capture circuit 4c.

Only a part of the channel swap circuits 11a through 11e and/or a part of the data swap circuits 16a, 16b, and 16c may reorder the bits depending on the data transmitted from the LVDS transmitter circuit 1.

In this manner, using the selector circuit 3 of this embodiment allows dealing with the change of a bit order of data received in a data transfer system flexibly to some extent while suppressing the increase of circuit scale when designing the image data transfer system. In particular, additionally providing the data swap circuits 16a, 16b, and 16c allows respective bits of the R data, G data, and B data to be output in orders desirable as image data for subsequent circuits.

An image data transfer system including the selector circuit according to the embodiment of the invention can be used for an apparatus that performs image processing, such as a digital copier, a digital television, and a facsimile apparatus. Moreover, this image data transfer system can be used in combination with a processor for processing image data, such as a SIMD (single-instruction multiple-data stream) processor.

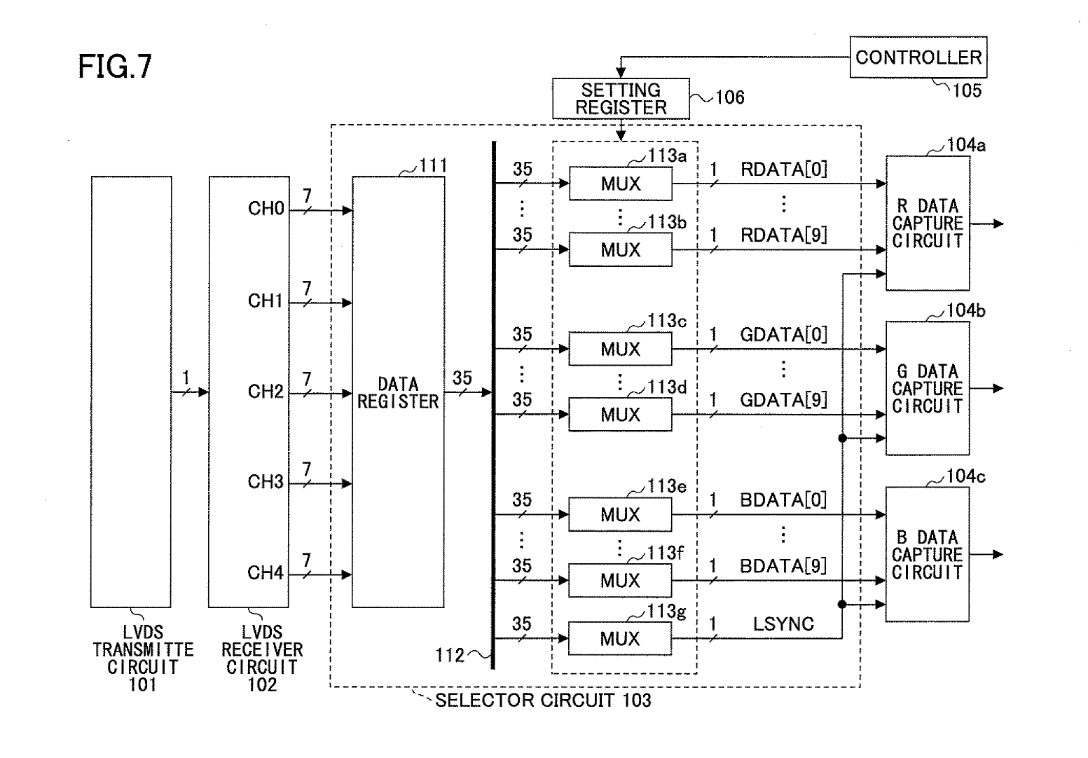

According to at least one embodiment, using the selector circuit of the invention allows dealing with the change of a bit order of data received in a data transfer system flexibly to some extent while suppressing the increase of circuit scale when designing an image data transfer system, and outputting data in a desirable bit order for subsequent circuits. In particular, further providing second swap circuits allows outputting data in a bit order desirable as image data for subsequent circuits. In particular, using simple circuits as first and second swap circuits is advantageous for preventing the increase of circuit scale. Compared to the circuit as illustrated in FIG. 7, which simply has the equal number of multiplexers to the number of bits of output data, the increase of circuit scale can be suppressed.

Although the invention has been described with respect to specific embodiments for a complete and clear disclosure, the appended claims are not to be thus limited but are to be construed as embodying all modifications and alternative constructions that may occur to one skilled in the art that fairly fall within the basic teachings herein set forth.

This patent application is based on Japanese Priority Patent Application No. 2010-060173 filed on Mar. 17, 2010, the entire contents of which are hereby incorporated herein by reference.

What is claimed is:

1. A selector circuit for selecting and outputting plural pieces of output data from input data including plural bits, each of the pieces of the output data including plural bits, the selector circuit comprising:
plural first swap circuits, each of the bits of the input data being input to any of the plural first swap circuits, the plural first swap circuits being configured to reorder and output the input bits or output the input bits without reordering;
a bus configured to transfer the bits output from the first swap circuits; and
plural data field specifying circuits respectively configured to select and take out a predetermined number of continuous bits on the bus,
wherein plural bits taken out by any of the data field specifying circuits are included in the respective pieces of the output data.

2. The selector circuit as claimed in claim 1, wherein the plural bits of the input data have a continuous order or are reordered by at least one of the first swap circuits to have a continuous order.

3. The selector circuit as claimed in claim 1, wherein each of the plural first swap circuits outputs the input bits without reordering or reverses an order of the input bits and outputs the input bits.

4. The selector circuit as claimed in claim 1, further comprising plural second swap circuits provided in respective subsequent stages of the data field specifying circuits and configured to output the bits taken out by the data field specifying circuits without reordering or reorder the bits taken out by the data field specifying circuits and output the reordered bits.

5. The selector circuit as claimed in claim 4, wherein the second swap circuits output the bits taken out by the data field specifying circuits without reordering or reverse an order of the bits taken out by the data field specifying circuits and output the bits.

6. The selector circuit as claimed in claim 1, further comprising a control data specifying circuit configured to select and take out at least one control bit on the bus, wherein the control bit is further included in the respective pieces of the output data.

7. The selector circuit as claimed in claim 1, wherein each of the pieces of the output data includes plural bits that constitute any of plural components of image data.
